(19) United States
(12) Patent Application Publication
(10) Pub. No.: US 2025/0081476 A1
(43) Pub. Date: Mar. 6, 2025

(54) INTEGRATED CIRCUIT WITH INDUCTOR IN MAGNETIC PACKAGE

(71) Applicant: TEXAS INSTRUMENTS INCORPORATED, Dallas, TX (US)

(72) Inventors: Hidetoshi Inoue, Oyama-shi (JP); Kenji Otake, NAGANO (JP); Sombuddha Chakraborty, Redwood City, CA (US); Taisuke Kazama, Plano, TX (US)

(21) Appl. No.: 18/459,230

(22) Filed: Aug. 31, 2023

(51) Int. Cl. H10N 35/00; H01L 23/00; H01L 23/495; H01L 25/065

(52) U.S. Cl. CPC H10D 1/20; H01L 23/49506; H01L 23/49589; H01L 24/32; H01L 25/0657; H01L 2224/32145; H01L 2224/32245; H01L 2225/06551; H01L 2924/1205; H01L 2924/182; H01L 2924/19104

(57) ABSTRACT

A packaged integrated circuit (IC) includes a package substrate, an electronic device on the package substrate, and metal interconnects coupled between the electronic device and the package substrate. The packaged IC also includes an insulation material on the package substrate and encapsulating the electronic device. The insulation material surrounds the metal interconnects. An inductor is over the electronic device and is coupled to the package substrate. A magnetic material is on the insulation material and encapsulates the inductor. The magnetic material is different from the insulation material.

### BACKGROUND

An inductor can store energy in a magnetic field when electric current flows through the inductor and can provide an electric current by discharging the stored energy. Inductors can have many applications, such as proximity sensing, energy storage, actuation, power transmission, and filtering. An inductor may be coupled to, or can be part of, an integrated circuit (IC), which can include circuits that operate with the inductor to support those and other applications. In some examples, the inductor and the corresponding circuits can be enclosed in an integrated circuit package, which can reduce the footprint of the integrated circuit and shorten the interconnects between the inductor and the circuits to which it connects.

### SUMMARY

In an example, a packaged integrated circuit (IC) includes a package substrate, an electronic device on the package substrate, and metal interconnects coupled between the electronic device and the package substrate. The packaged IC also includes an insulation material on the substrate and encapsulating the electronic device. The insulation material surrounds the metal interconnects. An inductor is over the electronic device and is coupled to the package substrate. A magnetic material is on the insulation material and encapsulates the inductor. The magnetic material is different from the insulation material.

In another example, a method includes encapsulating an electronic device attached to a package substrate with an insulation material, forming solder on first and second metal posts attached to the package substrate and surrounded by the insulation material, and attaching a coil to the solder on the first and second metal posts. The method may also include encapsulating the coil with a magnetic material.

### BRIEF DESCRIPTION OF THE DRAWINGS

FIG. 1 is a schematic diagram of a packaged integrated circuit (IC) including an inductor, in an example.

FIG. 2 is a schematic illustrating an epoxy containing particles suspended in a resin to form either the magnetic material or the insulation material, in an example.

FIG. 3 is a schematic illustrating a cross-sectional view of a packaged IC, in an example.

FIG. 4 is a schematic illustrating a top-down transparent view of a packaged IC, in an example.

FIG. 5 is a schematic illustrating a cross-sectional view of a packaged IC, in an example.

FIG. 6 is a flowchart illustrating a method of fabricating a packaged IC, in an example.

FIGS. 7, 8, 9, and 10 are schematics illustrating fabrication operations of a packaged IC as part of the method of FIG. 6, in an example.

FIGS. 11, 12, and 13 are schematics illustrating fabrication operations of a packaged IC as part of the method of FIG. 6, in an example.

FIGS. 14, 15, and 16 are schematics illustrating fabrication operations of a packaged IC as part of the method of FIG. 6, in an example.

### DETAILED DESCRIPTION

The same reference numbers or other reference designators are used in the drawings to designate the same or similar (either by function and/or structure) features.

Some packaged integrated circuits (ICs) may have an inductor and a semiconductor die attached to a package substrate. The inductor can be encapsulated in a magnetic material (e.g., a magnetic molding compound) to concentrate the magnetic fields generated by the inductor. The semiconductor may also be encapsulated in the same magnetic molding compound. However, such a magnetic molding compound may have a relatively low breakdown voltage, which can increase leakage current between the closely spaced metal interconnects of the semiconductor die.

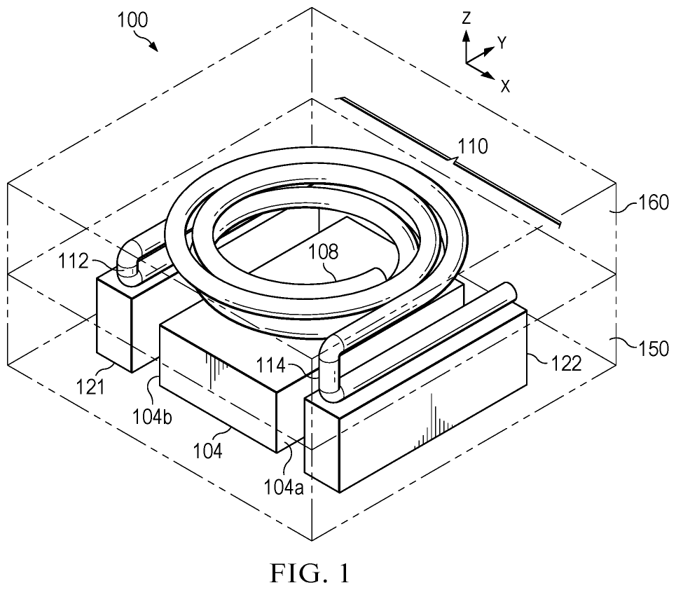

FIG. 1 is a schematic diagram of an example packaged integrated circuit (IC) 100 that includes an electronic device 104 on a package substrate (shown in other figures). Metal interconnects (shown in other figures) can attach electronic device 104 to the package substrate. The packaged IC 100 can include an insulation material 150 that encapsulates electronic device 105. The insulation material 150 can surround the metal interconnects. In the example of FIG. 1, an inductor 110 is over electronic device 104 and on the insulation material 150. The inductor 110 includes a coil portion 108 coupled to stilts 112 and 114. Stilts 112 and 114 are coupled to the package substrate at opposing sides 104a and 104b of the electronic device 104. Either or both of the stilts 112 and 114 of inductor 110 can be coupled to one or more interconnects of the electronic device 104 through the package substrate. Other components may be included within the packaged IC as well. A magnetic material 160 is on the insulation material 150 and encapsulates the inductor 110. The magnetic material 160 helps to concentrate the magnetic field generated by the inductor 110 to improve the efficiency of the inductor. The electronic device 104 and inductor 110 can be part of any of numerous devices such as power converters (e.g., buck converters, boost converters, etc.), filters, etc.

In the example of FIG. 1, the packaged IC 100 includes an inductor 110. In some other examples (not shown in the figures), the packaged IC 100 includes multiple (e.g., two) inductors 110 on the insulation material 150, the multiple inductors 110 are encapsulated in the magnetic material 160. The packaged IC 100 also include multiple metal posts (e.g., four) coupled between the multiple inductors and the package substrate, and the multiple metal posts are surrounded by the insulation material 150.

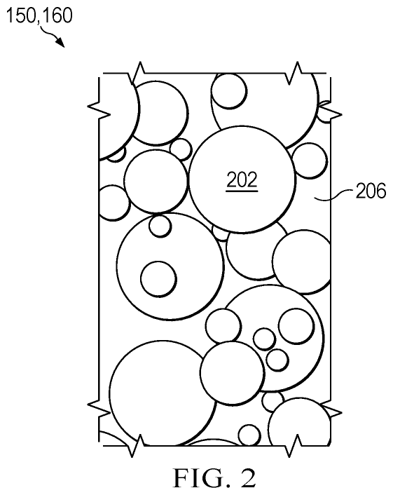

In one example, the magnetic material 160 is different from the insulation material 150. FIG. 2 is a view of the insulation material 150 and the magnetic material 160. In either case, the insulation material 150 and the magnetic material 160 can be an epoxy which includes particles 202 suspended in a resin 206. The type of particles 202 and the type of resin for the insulation material 150 can be different than the type of particles and type of resin for the magnetic material. In some examples, the insulation material 150 and the magnetic material 160 have the same types of resin but the particles are of different types. In one example, particles 202 in the insulation material are not electrically conductive, while the particles 202 in the magnetic material 160 are electrically conductive. In some examples, the insulation material 150 can be sealed by compression or transfer molding, but film-type molding materials (e.g., molded by a lamination process) can be used as well for the insulation material 150.

The particles 202 for the insulation material 150 can include silicon dioxide, silica and alumina, and other types of dielectric particles, and insulation material 150 can be an epoxy molding compound that can be molded. For the magnetic material 160, the particles 202 can include metal (e.g., iron) or other types of electrically conducive particles, and magnetic material 160 can be magnetic molding compound that can be molded. Using an epoxy to form the insulation material 150 advantageously provides sufficient mechanical strength to support the magnetic material 160.

Because the particles 202 in the epoxy for the insulation material 150 are not-electrically conductive while the particles 202 in the epoxy for the magnetic material 160 are electrically conductive, the breakdown voltage of the insulation material 150 is higher than the breakdown voltage of the magnetic material 160. Accordingly, because the electronic device 104 is encapsulated with the insulation material 150 and not the magnetic material 160, leakage current is much less likely to occur between the metal interconnects of the electronic device 104.

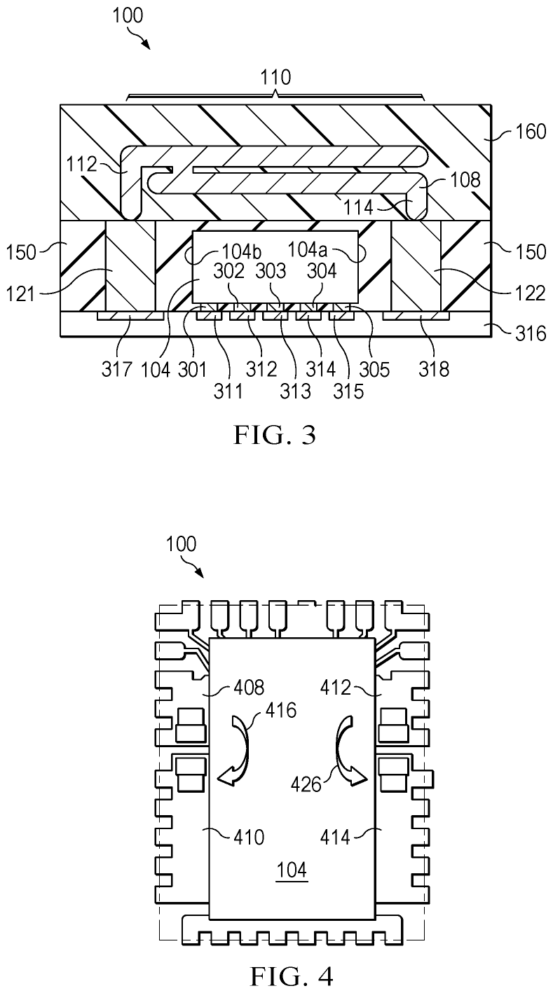

FIG. 3 is a cross-sectional view of the packaged IC 100 showing the electronic device 104 encapsulated in the insulation material 150, and the inductor 110 encapsulated in the magnetic material 160. The magnetic material 160 can concentrate the magnetic field in the inductor 110. Also, although the magnetic material 160 has a low break down voltage, because stilts 112 and 114 are more spaced apart (compared with the interconnects of electronic device 104), the leakage current between stilts 112 and 114 can be insignificant.

In the example of FIG. 3, the electronic device 104 can include a semiconductor die. The semiconductor die may be, for example, a controller IC for a power converter. The electronic device 104 is attached to a package substrate 316 by way of multiple metal interconnects 301, 302, 303, 304, and 305. Each metal interconnect is surrounded by insulation material 150, which can reduce the leakage current between adjacent metal interconnect compared with a case where each metal interconnect is surrounded by magnetic material 160. Although five metal interconnects 301-305 are shown in the example of FIG. 3, the number of metal interconnects depends on the number of terminals of the semiconductor die. The metal interconnects 301-305 can be metal such as copper. In one example, the package substrate 316 can be a lead frame or other suitable type of metal structure to which electronic device 104 can be attached.

Metal (e.g., copper) posts 321 and 322 are included within and surrounded by the insulation material 150. In some examples, the metal posts can also be metal clips or metal slugs. Metal post 321 is coupled between stilt 112 and the package substrate 316, and metal post 322 is coupled between stilt 114 and the package substrate 316. The package substrate 316 includes metal (e.g., copper) pads 317 and 318. Metal pad 317 is coupled to metal post 321, and metal pad 318 is coupled to metal post 322. The metal posts 321 and 322 provide electrical connections between inductor 110 and the metal pads 317 and 318. The package substrate 316 can include additional metal pads 311, 312, 313, 314, and 315 to which corresponding metal interconnects 301-305 can be coupled. The package substrate 316 can also include metal conductors coupled between metal pads 317/318 and one or more of metal pads 311-315 to provide electrical connections between inductor 110 and electronic device 104.

Besides reducing leakage between metal interconnects, encapsulating the semiconductor die in insulation material 150 can also reduce the loop inductance between the metal conductors of package substrate 316 by shielding the metal conductors from magnetic material 160. A loop inductance can be created between two metal conductors (e.g., traces) on package substrate 316 that are otherwise not electrically shorted but both are in physical contact with a material. The loop inductance can be proportional to the impedance of a current path via the mold compound and across the two metal conductors, which in turn is proportional to the magnetic permeability of the material and inversely proportional to the width the metal conductors. If the metal conductors are in physical contact with the magnetic material 160, a large loop inductance may result due to the large magnetic permeability of the magnetic material. But if the metal conductors are in physical contact with the insulation material 150, a small loop inductance may result due to the small magnetic permeability of the insulation material. A small loop inductance is desirable because the loop inductance adds to the switching loss, especially in a case where packaged IC 100 operates as a switch mode converter and conducts a high current through the metal conductors.

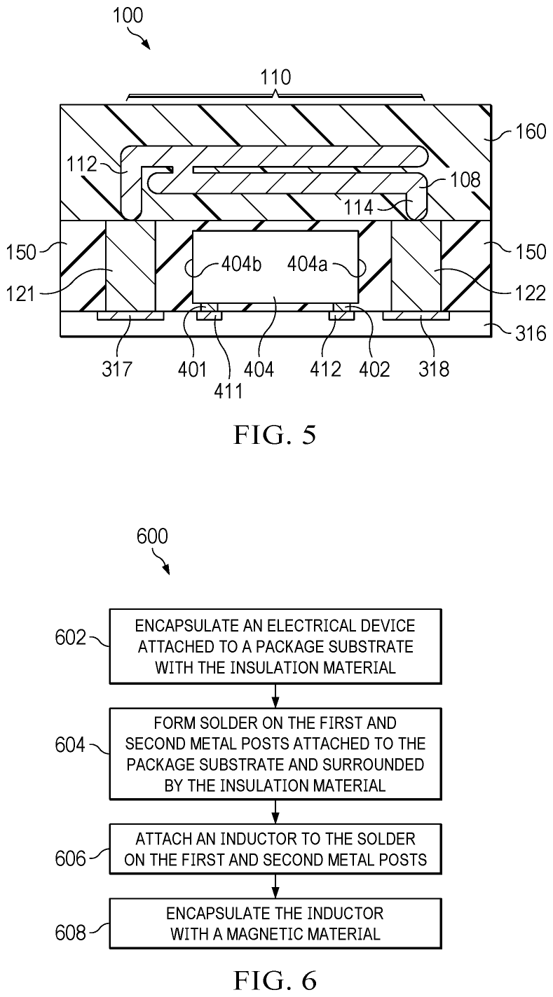

FIG. 4 is a top-down transparent view of the packaged IC 100 including electronic device 104 on metal conductors 408, 410, 412, and 414. Metal conductors 408 in FIG. 4 can be part of the package substrate 316. There can be loop inductance 416 between metal conductors 408 and 410, and loop inductance 426 between metal conductors 412 and 414. If the magnetic material 160 were to encapsulate the electronic device 104 and be in physical contact with metal conductors 408, 410, 412, and 414, the loop inductances 416 and 426 may increase, as explained above.

In the example of FIG. 3, however, the insulation material 150 encapsulates the electronic device 104 as well as the package substrate 316. By encapsulating the package substrate 316 with the insulation material 150, the insulation material 150 also shields the metal conductors from the magnetic material 160, which can reduce the magnetization of the metal conductors and the loop inductance. Accordingly, the loop inductance of the packaged IC 100 can be reduced compared to the loop inductance that would result if the package substrate 316 was not so encapsulated. In one example, the loop inductance of a packaged IC in which the package substrate and inductor are encapsulated with only magnetic material can be 214 pF, but the loop inductance of the packaged IC 100 described herein in which the package substrate 316 is encapsulated with the insulation material 150 can be much lower, e.g., 76 pF.

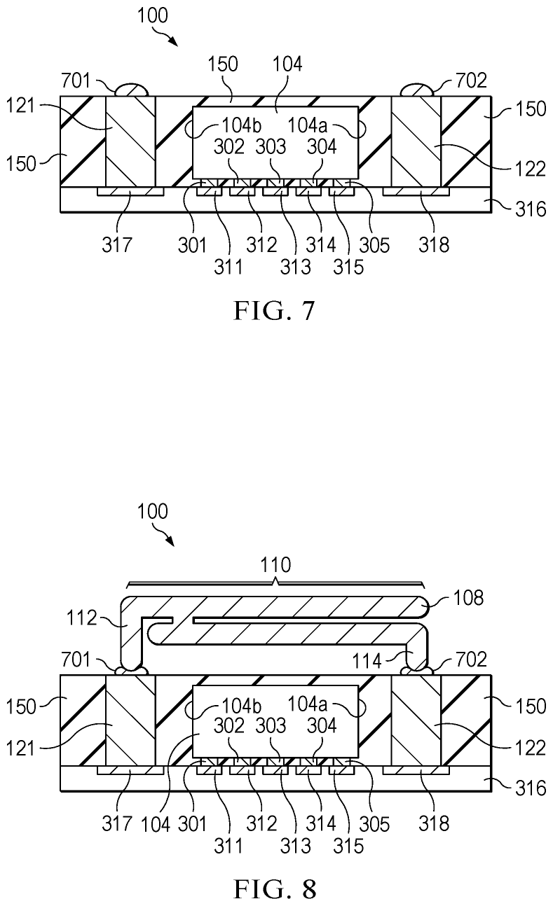

FIG. 5 is a schematic diagram of packaged IC 100 in which the electronic device 104 includes a capacitor 504. Capacitor 504 is a two-terminal device and has metal interconnects 506 and 508 which are coupled to, respectively, metal pads 511 and 512 on the package substrate 316.

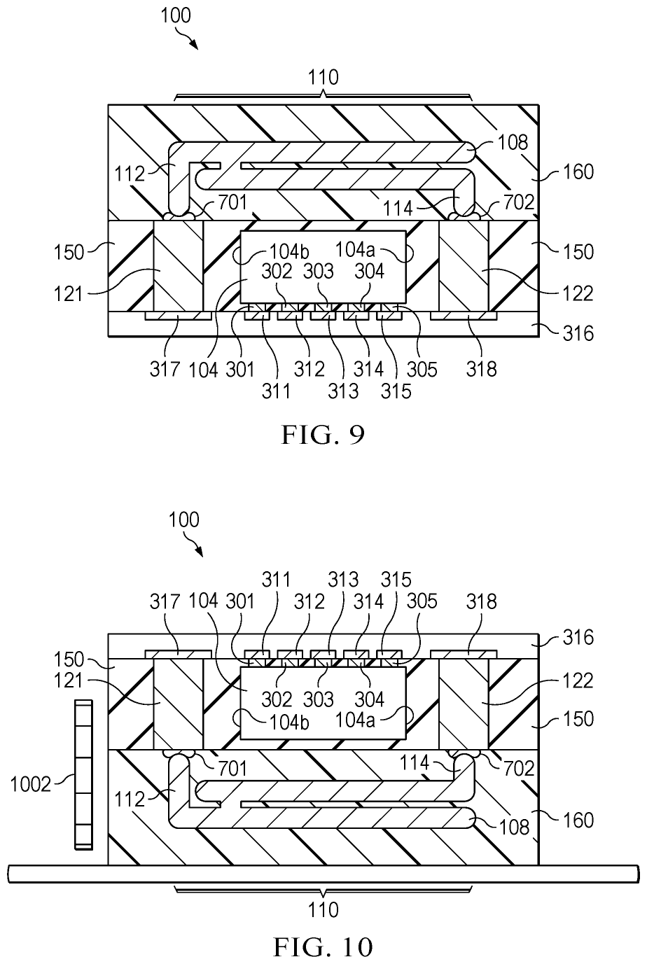

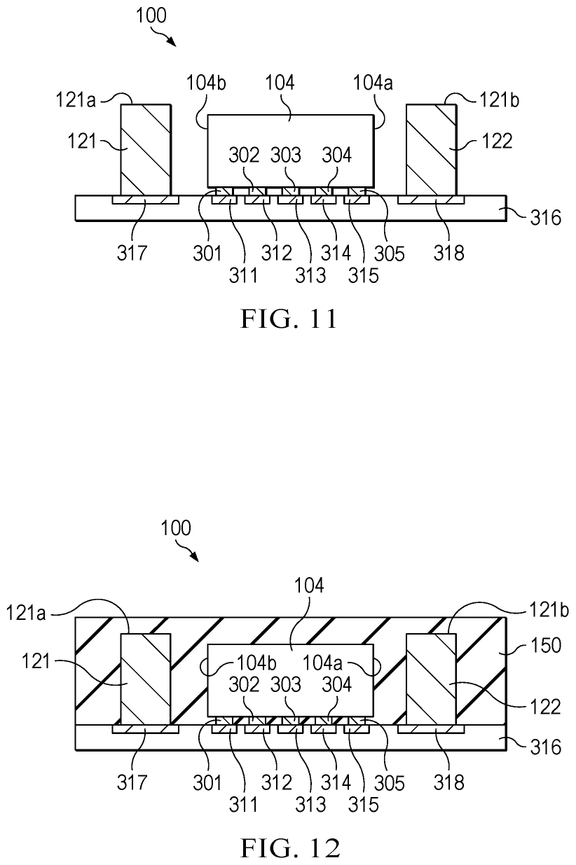

FIG. 6 is a flowchart of an example method 600 for fabricating at least a portion of the packaged IC 100, and FIGS. 7-16 are schematics illustrating cross-sections of portions of the packaged IC 100 during various stages of fabrication.

Referring to FIG. 6 and FIG. 7, in operation 602, electronic device 104 attached to the package substrate 316 can be encapsulated with the insulation material 150. Metal posts 321 and 322 are also attached to the package substrate 316 and are surrounded by the insulation material 150. FIG. 7 illustrates the metal interconnects 301-305 of the electronic device 104 attached to the corresponding metal pads 311-315 of the package substrate 316. As described above, the electronic device 104 may be a semiconductor die, in which case the semiconductor die may previously have been fabricated through wafer-level processing (e.g., multiple semiconductor dies fabricated on a single wafer and then singulated into the individual dies). Metal posts 321 and 322 are coupled to the package substrate 316 by way of the respective metal pads 317 and 318. The metal posts 321 and 322 are surrounded by the insulation material 150. The insulation material 150 also encapsulates the electronic device 104 and can also encapsulate the package substrate 316.

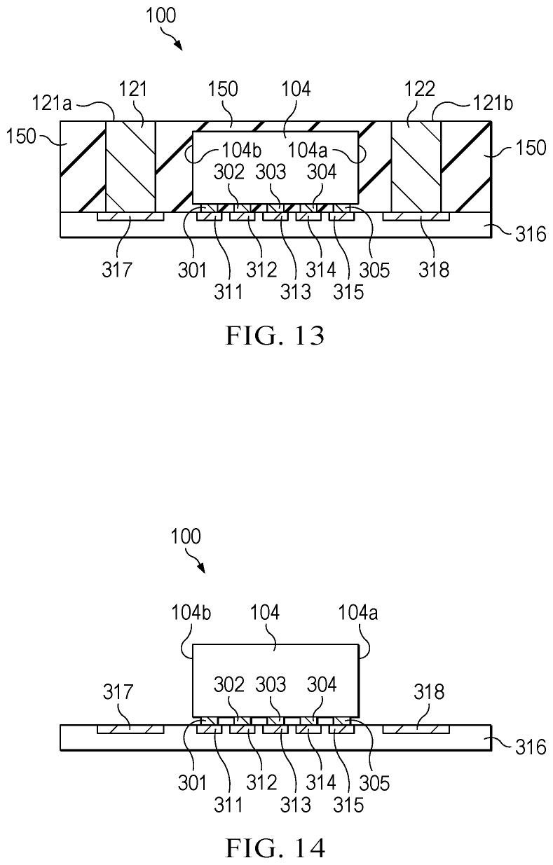

FIGS. 11-13 illustrate an example process of encapsulating electronic device 104 and forming metal posts 321 and 322. Referring to FIG. 11, the electronic device 104 can be attached to the package substrate 316 by reflowing solder between the metal interconnects 301-305 and the corresponding metal pads 311-315. Further, the metal posts 321 and 322 can be formed on the package substrate 316 by electroplating, or by other techniques (e.g., by soldering the metal posts/clips onto the package substrate 316), and a device assembly is formed. For example, a seed layer can be formed on the metal pads 317 and 318. The seed layer can include a copper species. The copper is then electroplated on the metal pads 317 and 318.

Also, referring to FIG. 12, insulation material 150 can be deposited on package substrate 316 to cover metal posts 321 and 322, electronic device 104, and the interconnects between the electronic device 104 and package substrate 316. In some examples, the device assembly of FIG. 10 can be disposed in a mold chase (e.g., by a nozzle), and the insulation material 150 in molten/liquid form can be deposited into the mold chase to cover package substrate 316, metal posts 321 and 322, electronic device 104, and the interconnects. The insulation material 150 can then be cured to become in solid form and encapsulate metal posts 321 and 322, electronic device 104, and the interconnects between the electronic device 104 and package substrate 316. As illustrated in FIG. 11, the top surfaces 321a and 322a of metal posts 321 and 322 are covered by the insulation material 150.

Further, referring to FIG. 13, a grind process can be performed to some of the insulation material 150 to expose top surfaces 321a and 322a of, respectively, metal posts 321 and 322. The grind process can be a mechanical grind process. Solder 701 and 702 (of FIG. 7) can then be formed on the exposed top surfaces 321a and 322a of the respective metal posts 321 and 322.

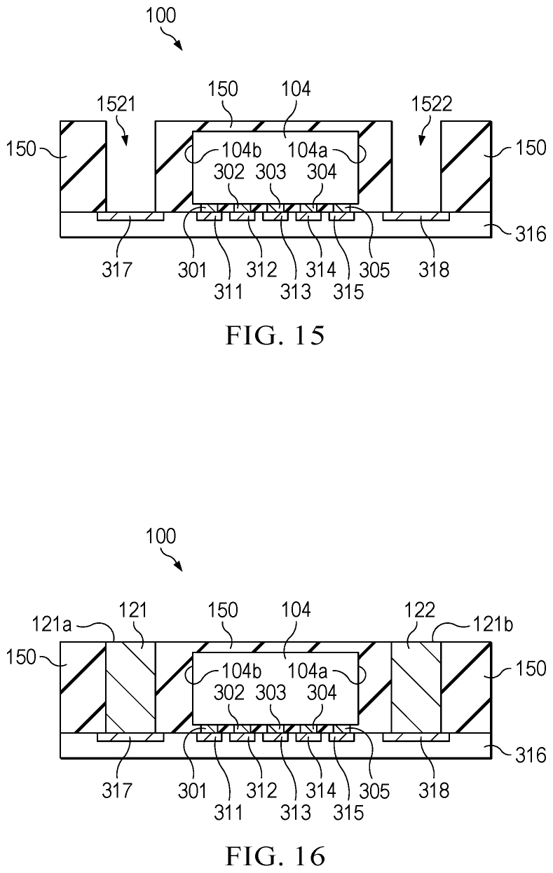

FIGS. 14-16 illustrate another example process of encapsulating electronic device 104 and forming metal posts 321 and 322. Referring to FIG. 14, the electronic device 104 is attached to the package substrate 316 to form a device assembly, for example, as described above.

Also, in FIG. 15, the device assembly of FIG. 14 is disposed in a mold chase, and the insulation material 150 in molten/liquid form can be deposited into the mold chase to cover package substrate 316, electronic device 104, and the interconnects. In some examples, the mold chase has protrusions coinciding with the locations of the metal pads 317 and 318. The protrusions of the mold chase prevent the insulation material 150 from forming over the metal pads 317 and 318 thereby leaving voids 1521 and 1522 in the insulation material 150. In some examples, voids 1521 and 1522 can be formed by drilling the insulation material 150 after the material is cured and solidifies.

Further, in FIG. 16, metal posts 321 and 322 in the voids 1521 and 1522 within the insulation material 150. In one example, a seed layer can be formed within the voids 1421 and 1422 on the metal pads 317 and 318. The seed layer can include a copper species. The copper is plated on the metal pads 317 and 318 and inner walls of the insulation material 150 within the voids 1421 and 1422. The metal (e.g., copper) forms within the void and eventually fills the voids as shown in FIG. 15.

Referring again to FIG. 6 and FIG. 7, in operation 604, solder layers (e.g., solder layers 701 and 702 of FIG. 7) are formed on first and second metal posts (e.g., metal posts 321 and 322) attached to the package substrate 316 and surrounded by the insulation material.

Further, referring to FIG. 6 and FIG. 8, in operation 606, an inductor (e.g., inductor 110) is attached to the solder layers formed on the first and second metal posts. For example, the stilts 112 and 114 of inductor 110 attached to solder layers 701 and 702, respectively. In one example, the inductor 110 can be placed on solder layers 701 and 702 by a pick-and-place process, and the solder is heated to reflow the solder.

Also, referring to FIG. 6 and FIG. 9, the inductor can be encapsulated with a magnetic material (e.g., magnetic material 160), as described above. In some examples, the device assembly of FIG. 8 including inductor 110 on insulation material 150 can be disposed in a mold chase, and magnetic material 160 in molten/liquid form can be deposited into the mold chase to cover inductor 110 and insulation material 150. The magnetic material 160 can then be cured to become in solid form and encapsulate inductor 110. Referring to FIG. 10, after the magnetic material 160 is solidified, part of the magnetic material 160 can removed by dicing with a saw 1002.

The operations described in FIGS. 6-16 can be performed as part of a packaging process on a semiconductor die after the die is singulated from a wafer. Accordingly, the encapsulation of the semiconductor die in the insulation material 150 needs not be performed in wafer-level processing operation, which can reduce the overall cost and complexity of the fabrication operation of IC 100.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Modifications are possible in the described embodiments, and other embodiments are possible, within the scope of the claims.

What is claimed is:

1. A packaged integrated circuit (IC) comprising:
a package substrate;
an electronic device on the package substrate;
metal interconnects coupled between the electronic device and the package substrate;
an insulation material on the package substrate and encapsulating the electronic device, the insulation material surrounding the metal interconnects;
an inductor over the electronic device and coupled to the package substrate; and
a magnetic material on the insulation material and encapsulating the inductor, in which the magnetic material is different from the insulation material.

2. The packaged IC of claim 1, wherein the insulation material includes non-electrically conductive particles and a first epoxy resin in which the non-electrically conductive particles are suspended.

3. The packaged IC of claim 2, wherein the magnetic material includes metal particles and a second epoxy resin in which the metal particles are suspended.

4. The packaged IC of claim 1, wherein the insulation material has a higher breakdown voltage than the magnetic material.

5. The packaged IC of claim 1, wherein the electronic device includes a semiconductor die.

6. The packaged IC of claim 1, wherein the electronic device includes a capacitor.

7. The packaged IC of claim 1, wherein the inductor has a coil portion, a first stilt, and a second stilt, in which the first and second stilts are coupled to the package substrate at opposing sides of the electronic device.

8. The packaged IC of claim 7, further comprising:
a first metal post coupled between the first stilt and the package substrate, the first metal post surrounded by the insulation material; and
a second metal post coupled between the second stilt and the package substrate, the second metal post surrounded by the insulation material.

9. The packaged IC of claim 8, wherein the package substrate includes:
a first metal pad coupled to the first metal post;
a second metal pad coupled to second metal post; and
third metal pads coupled to respective metal interconnects.

10. The packaged IC of claim 1, wherein the insulation material covers at least part of the package substrate.

11. A packaged integrated circuit (IC) comprising:
a lead frame;
a semiconductor die coupled to the lead frame;
an insulation material on the lead frame and encapsulating the semiconductor die, the insulation material including insulation particles and a first epoxy resin in which the insulation particles are suspended;
an inductor over the semiconductor die and coupled to the lead frame; and
a magnetic material on the insulation material and encapsulating the inductor.

12. The packaged IC of claim 11, wherein the magnetic material includes metal particles and a second epoxy resin in which the metal particles are suspended.

13. The packaged IC of claim 11, wherein the insulation material has a higher breakdown voltage than the magnetic material.

14. The packaged IC of claim 11, wherein the inductor has a coil portion, a first stilt, and a second stilt, in which the first and second stilts are coupled to the lead frame at opposing sides of the semiconductor die; and the packaged IC further comprises:
a first metal post coupled between the first stilt and the lead frame, the first metal post surrounded by the insulation material; and
a second metal post coupled between the second stilt and the lead frame, the second metal post surrounded by the insulation material.

15. The packaged IC of claim 11, wherein the insulation material covers at least part of the lead frame.

16. A method comprising:
encapsulating an electronic device attached to a package substrate with an insulation material;
forming solder on first and second metal posts attached to the package substrate and surrounded by the insulation material;
attaching an inductor to the solder on the first and second metal posts; and
encapsulating the inductor with a magnetic material.

17. The method of claim 16, further comprising forming the first and second metal posts on the package substrate, and encapsulating the electronic device with the insulation material includes encapsulating the electronic device and the first and second metal posts with the insulation material.

18. The method of claim 16, further comprising:
encapsulating the package substrate and the electronic device with the insulation material;
forming first and second openings in the insulation material; and
forming the first and second metal posts in, respectively, the first and second openings.

19. The method of claim 18, wherein forming the first and second openings in the insulation material includes at least one of: molding the insulation material with a mold chase with protrusions, or drilling the insulation material.

20. The method of claim 16, wherein the insulation material includes non-electrically conductive particles and a first epoxy resin in which the non-electrically conductive particles are suspended.
